(19) United States
(12) Patent Application Publication
(10) Pub. No.: US 2014/0077817 A1
(43) Pub. Date: Mar. 20, 2014

(54) METHOD FOR THE CONTROL AND HANDLING OF ELECTROCHEMICAL CELLS OR BATTERIES, ELECTROCHEMICAL CELL AND BATTERY

(71) Applicant: Tim Schaefer, Harztor (DE)

(72) Inventor: Tim Schaefer, Harztor (DE)

(73) Assignee: Li-Tec Battery GmbH, Kamenz (DE)

(21) Appl. No.: 14/007,805

(22) PCT Filed: Mar. 14, 2012
(86) PCT No.: PCT/EP12/01146

§ 371 Date: Nov. 27, 2013

(30) Foreign Application Priority Data
Mar. 31, 2011 (DE) 10 2011 015 746.8

(51) Int. Cl. G01R 31/36

(52) U.S. Cl. CPC G01R 31/3606; G01R 31/3662
USPC 324/430; 324/426

(57) ABSTRACT

The invention relates to a method for handling and servicing an electrochemical cell (1), preferably a battery having a number of electrochemical cells (1), comprising a controller (3), in particular a cell controller, preferably a battery controller, at least one sensor (4) connected to the controller (3) for acquiring parameter data (D_{Par.}) of the electrochemical cell (1) or the battery, a storage device (5), which comprises preferably a non-volatile memory, in particular a flash memory, and a unit (2) for data transmission, said method comprising the following steps: (S1) acquiring parameter data (D_{Par.}) of the electrochemical cell (1) or the battery, (S2) feeding the acquired parameter data (D_{Par.}) to the controller (3), (S3) calculating the control data (D_{Str.}) as a function of the supplied parameter data (D_{Par.}) with the controller (3), (S4) feeding the control data (D_{Str.}) to the storage device (5), (S5) reading out the control data (D_{Str.}) of the storage device (5) to the unit (2) for data transmission, and (S6) transmitting the read-out control data (D_{Str.}) to a display device via the unit (2) for data transmission, in particular transmitting the read-out control data (D_{Str.}) wirelessly to the display device via the unit (2) for data transmission.

The entire content of the DE 10-2011-015746 priority application is herewith incorporated by reference into the present application.

The invention relates to a method for the handling and servicing of an electrochemical cell, a method for the handling and servicing of a battery comprising said electrochemical cells, an electrochemical cell designed to realize the method as well as a corresponding battery comprising said electrochemical cells.

Electrochemical energy storages, also referred to as electrochemical or galvanic cells in the following, are frequently produced in the form of stackable units, wherein by combining a plurality of such cells, so-called batteries can be produced for various applications, particularly for use in electrically operated motor vehicles. The invention will be described with reference to its use in a motor vehicle, whereby it is however pointed out that such a method and accordingly designed electrochemical cell, or such a battery respectively, can also be operated independently of motor vehicles, e.g. in stationary use.

Methods for handling and servicing electrochemical cells and/or batteries as well as accordingly designed electrochemical cells and/or batteries are known from the prior art, albeit associated with complicated handling and servicing.

The object of the present invention is that of an improved technical teaching for the handling and servicing of electrochemical cells and/or batteries.

This object is accomplished by a method in accordance with claim 1 for the handling and servicing of an electrochemical cell, or battery respectively, comprising a plurality of such electrochemical cells, and by an electrochemical cell in accordance with claim 11, as well as by a battery in accordance with claim 16 comprising a plurality of such electrochemical cells. The subclaims relate to advantageous further developments of the invention.

In accordance with a first aspect, a method for the handling and servicing of an electrochemical cell, preferably a battery having a plurality of such electrochemical cells, comprising a controller, particularly a cell controller, preferably a battery controller, at least one sensor connected to the controller for acquiring parameter data on the electrochemical cell or battery, a storage apparatus preferably having non-volatile memory, particularly a flash memory, and a data transmission unit, is accomplished by the method comprising the following steps: acquiring parameter data on the electrochemical cell or battery respectively, feeding the acquired parameter data to the cell controller, the controller calculating control data as a function of the supplied parameter data, feeding the control data to the storage apparatus, reading out the control data from the storage apparatus to the data transmission unit, and the data transmission unit transmitting the read-out control data to a display apparatus, the data transmission unit particularly wirelessly transmitting the read-out control data to a display apparatus.

One advantage of this design is that a user is able to readily determine the status of the electrochemical cell or battery respectively from the control data, e.g. for handling or servicing purposes, so as to initiate measures for maintaining or increasing the efficiency or safety as needed. It is also possible to selectively replace electrochemical cells or batteries during maintenance work in a shop in order to for example increase the overall performance when upgrading. This is advantageous particularly for determining the status of a slightly damaged electrochemical cell or an electrochemical cell no longer covered by maintenance service, respectively a corresponding arrangement of electrochemical cells and/or a battery, as the cells or the cell arrangement or the battery should not be transported. Moreover, obtaining control data and/or parameter data information in particular is advantageous from a safety standpoint with respect to a technician or to service, particularly in the case of large battery assemblies. This is of particular advantage when the battery fails, protective components have been actuated or a battery management system BMS and/or battery management monitoring system BMMS or a protective circuit malfunctions or ceases operation.

Control data is to be understood in the present context not only as a plurality of control data, but, where applicable, also one single control datum. Accordingly, predetermined control values in the present context is not only to be understood as a plurality of predetermined control values, but also, where applicable, one single predetermined control value.

An electrochemical cell in the present context is to be understood as an electrochemical energy storage; i.e. a device which stores energy in chemical form, dispenses the energy to a load in electrical form, and can preferably also absorb it in electrical form from a charging device. Galvanic cells and fuel cells are important examples of such electrochemical energy storages. The electrochemical cell comprises at least one first and one second device for storing electrically different charges as well as means for producing an operative electrical connection between said two devices, whereby charge carriers can be positioned between the two devices. A means for producing an operative electrical connection refers for example to an electrolyte acting as an ionic conductor.

A sensor is to be understood as a device for acquiring at least one parameter of the electrochemical cell or battery. This can include devices for detecting electrical variables such as the voltage, current, capacitance or charge, for example, or also the temperature, pressure or even the installed position of the electrochemical cell or battery.

In accordance with a further aspect, a method for the handling and servicing of an electrochemical cell comprising at least one sensor for acquiring parameter data on the electrochemical cell or battery, a storage apparatus preferably having non-volatile memory, particularly a flash memory, and a data transmission unit, is accomplished by the method comprising the following steps: acquiring parameter data on the electrochemical cell or battery respectively, feeding the acquired parameter data to the storage apparatus, reading out the stored parameter data from the storage apparatus to the data transmission unit, and the data transmission unit transmitting the read-out parameter data to a display apparatus, the data transmission unit particularly wirelessly transmitting the read-out parameter data to a display apparatus.

One advantage of this design is that a user is able to readily determine the status of the electrochemical cell or battery respectively from the parameter data, e.g. for handling or servicing purposes, so as to initiate measures for maintaining or increasing the efficiency or safety as needed.

Parameter data is to be understood in the present context not only as a plurality of parameter data, but also, where applicable, one single parameter datum. Accordingly, predetermined parameter values in the present context is not only to be understood as a plurality of predetermined parameter values, but also, where applicable, one single predetermined parameter value.

With the handling and servicing methods, it is preferential for at least one parameter data on the electrochemical cell or battery acquired by the sensor to be selected from among a parameter group which includes at least one of the following parameters: the state of charge (SOC) of the electrochemical cell or battery, the temperature of the electrochemical cell or battery, the voltage of the electrochemical cell or battery, the load on the electrochemical cell or battery, the charging characteristics of the electrochemical cell or battery, the status of a protective apparatus, particularly a PTC resistor or a power cutoff apparatus, the functioning of the sensor or the pressure in the electrochemical cell or battery respectively. One preferential embodiment provides for an algorithm during servicing or periodically which checks and saves the parameters, particularly the operational states such as the temperature, load, charging characteristics and/or the functioning of the protective apparatus and the sensors in or on the electrochemical cell or battery, whereby said data is then locally available if needed without high analytical expense.

Further proven advantageous is for the method to comprise the step: reading out the bar code information associated with the electrochemical cell or battery.

It is particularly preferential for the method to comprise at least one of the steps: activating the electrochemical cell or battery via the data transmission unit as a function of the displayed control data or displayed parameter data respectively, effecting a treatment of the electrochemical cell or battery or releasing the electrochemical cell or battery for transport. One advantage of this method lies in being able to improve the safety and provide a basis for evaluating whether a component might be subject to a ban on being transported or which state, particularly state of charge (SOC), the electrochemical cell or battery is in. In large-scale and small-scale assembly cells, protective apparatus such as PTC resistors or power cutoff apparatus and the like are disposed on the cell contacts, in cells or on or in the battery respectively. Upon or subsequent to being actuated, the cell or the battery may be damaged in a high state of charge so that it is advantageous to be able to draw conclusions as to the specific model of the components, protective apparatus, the testing status of the components which can otherwise only be obtained at great cost in electrical/electrochemical shops or battery institutes. Drawing on the production lot, the provided UN certification of the components and the current data on the components and protective apparatus, the user is able to carry out extensive preliminary prognoses and/or maintenance and/or repairs.

The method can further comprise the step: the electrochemical cell or battery being activated via the data transmission unit as a function of the control data display step and the bar code information read-out step, respectively as a function of the parameter data display step and bar code information read-out step. One advantage of this method is that specific steps can be initiated to improve battery operation efficiency and contribute to the long-term overall efficiency of the system.

It is preferential in the handling and servicing method for at least one parameter data on the electrochemical cell or battery acquired by the sensor to be selected from among a parameter group which includes at least one of the following parameters: the number of previous charging cycles in the electrochemical cell or battery, the characteristics of the previous charging cycles in the electrochemical cell or battery, the capacitance of the electrochemical cell or battery at the last full charge, the original capacitance of the electrochemical cell or battery, the maximum voltage of the electrochemical cell or battery at the last full charge, the original voltage of the electrochemical cell or battery, or the manufacturer of the electrochemical cell or battery.

In accordance with a second aspect, an electrochemical cell having a controller, particularly a cell controller, comprising at least one sensor for acquiring parameter data on the electrochemical cell or a battery respectively, at least one storage apparatus, preferably having non-volatile memory, particularly a flash memory, and at least one signal transmission unit, particularly a wireless signal transmitting unit, is accomplished by the electrochemical cell being designed to perform one of the above-cited methods.

Preferentially, the sensor for the electrochemical cell is designed to acquire parameter data on the electrochemical or on the battery respectively which is selected from among a parameter group comprising at least one of the following parameters: the state of charge of the electrochemical cell or battery, the temperature of the electrochemical cell or battery, the voltage of the electrochemical cell or battery, the load on the electrochemical cell or battery, the charging characteristics of the electrochemical cell or battery, the status of a protective apparatus, particularly a PTC resistor or a power cutoff apparatus, on or in the electrochemical cell or on or in the battery respectively, the functioning of the sensor or the pressure in the electrochemical cell or battery respectively.

The sensor of the electrochemical cell can furthermore comprise at least one of the following sensor units: a state of charge sensor unit, a temperature sensor unit, a voltage sensor unit or a pressure sensor unit.

It has proven advantageous for the storage apparatus to be designed to store at least one of the following parameters: the number of previous charging cycles in the electrochemical cell or battery, the characteristics of the previous charging cycles in the electrochemical cell or battery, the capacitance of the electrochemical cell or battery at the last full load, the original capacitance of the electrochemical cell or battery, the maximum voltage of the electrochemical cell or battery at the last full load, the original voltage of the electrochemical cell or battery, or the manufacturer of the electrochemical cell or battery.

The electrochemical cell can furthermore comprise an activating apparatus which is designed to activate the electrochemical cell or the battery respectively via the wireless signal transmission unit.

The present invention moreover relates to an arrangement of such electrochemical cells designed for use in a motor vehicle. The present invention particularly relates to a battery having a plurality of the above-cited electrochemical cells.

This design has the advantage of preventing damage to the electrochemical cells in the event of improper installation.

The features of the described and further embodiments of the invention can advantageously be combined with one another, thereby putting further embodiments of the invention which are unable to be conclusively and completely described herein at the disposal of one skilled in the art.

The following will make reference to the figures in describing the invention on the basis of preferred embodiments in greater detail. Shown are:

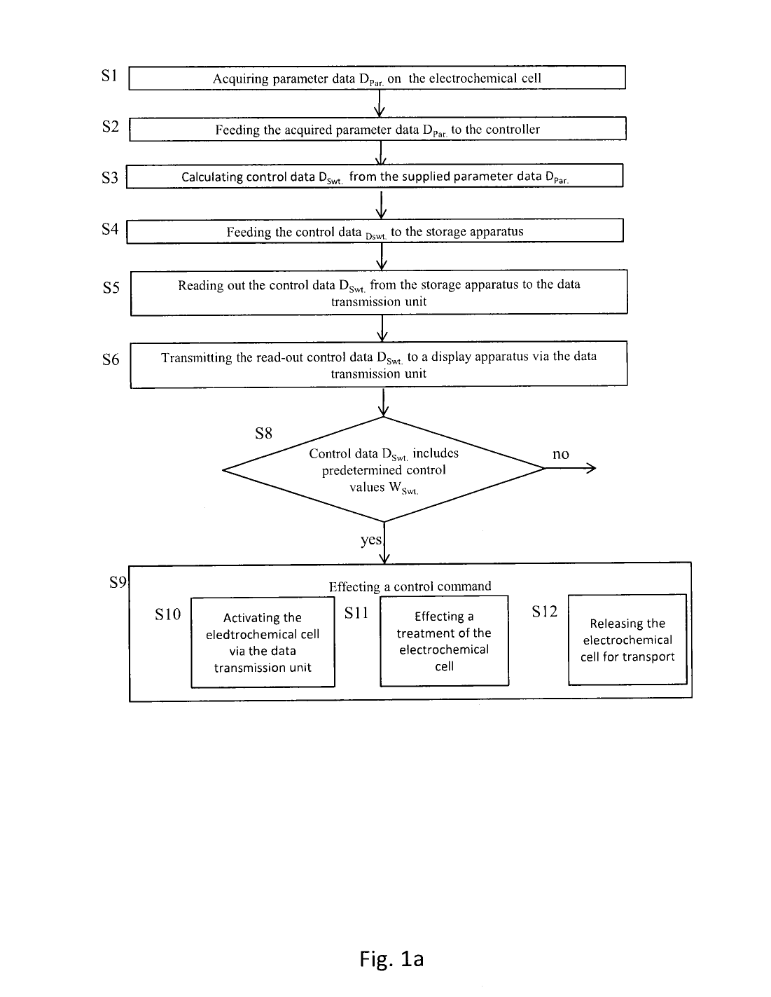

FIG. 1a a flow chart on the handling and servicing of electrochemical cells or a battery respectively according to a first method embodiment,

FIG. 1b a flow chart on the handling and servicing of electrochemical cells or a battery respectively according to a modification of the first method embodiment,

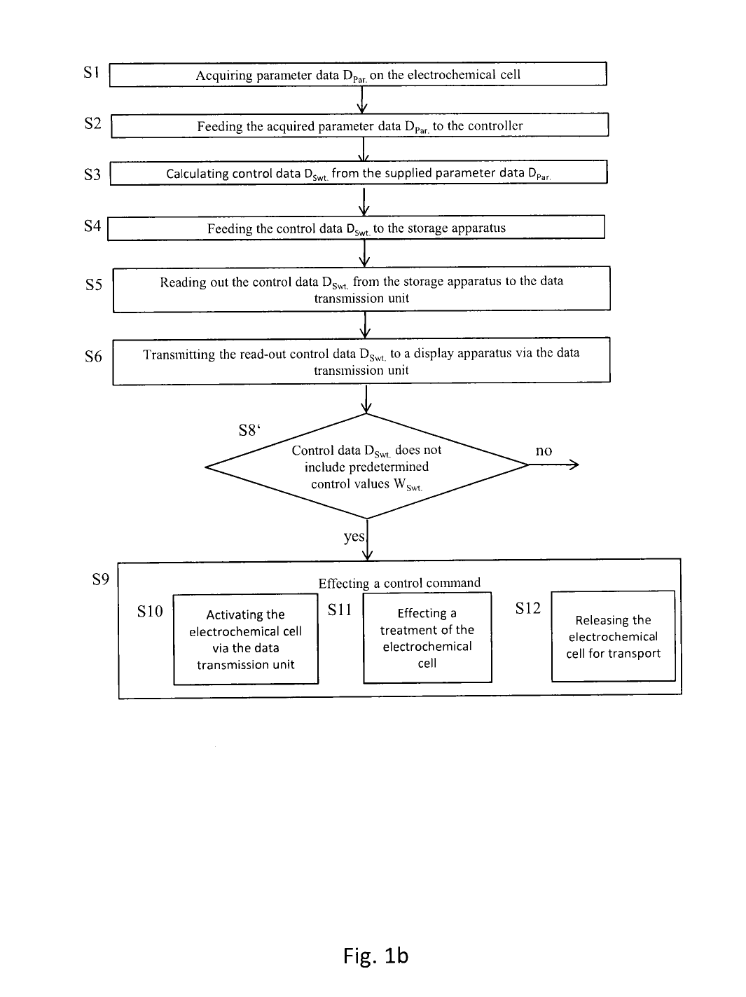

FIG. 2a a flow chart on the handling and servicing of electrochemical cells or a battery respectively according to a second method embodiment,

FIG. 2b a flow chart on the handling and servicing of electrochemical cells or a battery respectively according to a modification of the second method embodiment,

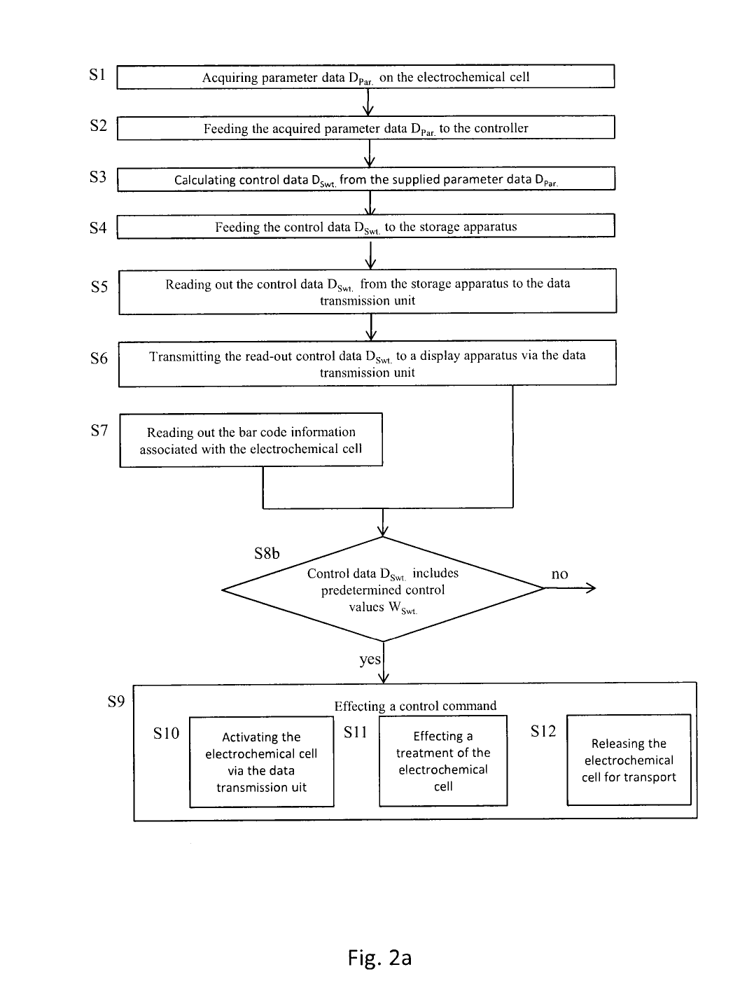

FIG. 3a a flow chart on the handling and servicing of electrochemical cells or a battery respectively according to a third method embodiment,

FIG. 3b a flow chart on the handling and servicing of electrochemical cells or a battery respectively according to a modification of the second method embodiment,

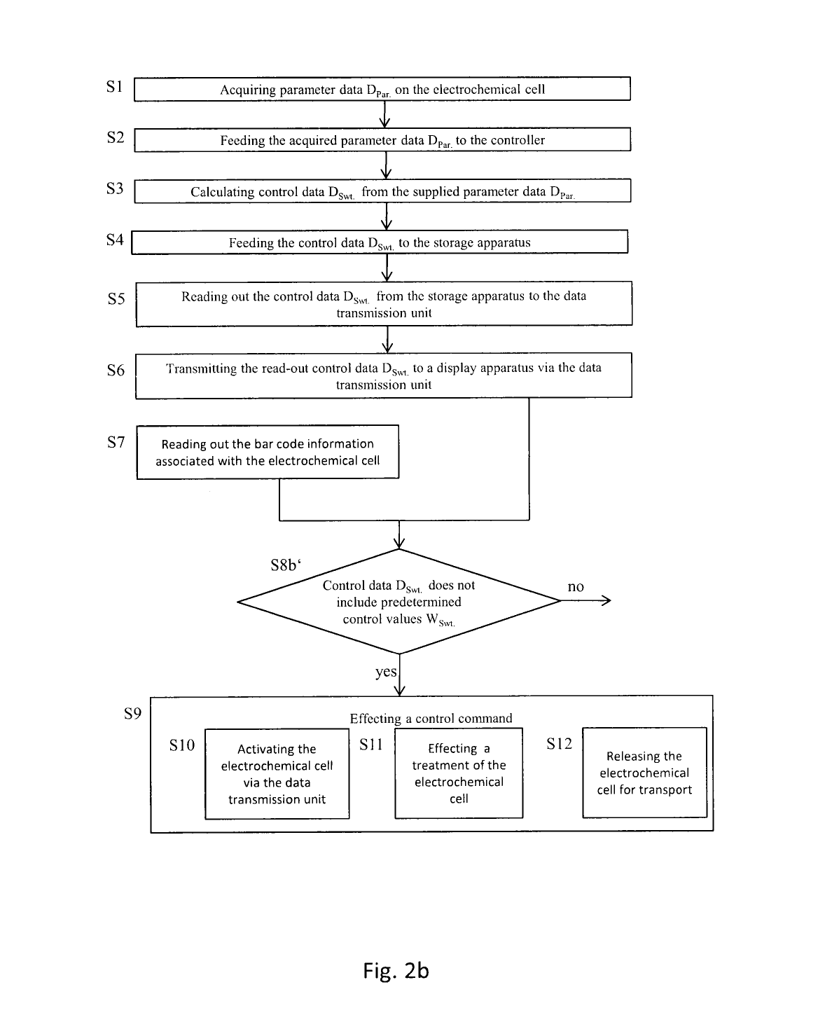

FIG. 4a a flow chart on the handling and servicing of electrochemical cells or a battery respectively according to a fourth method embodiment,

FIG. 4b a flow chart on the handling and servicing of electrochemical cells or a battery respectively according to a modification of the second method embodiment,

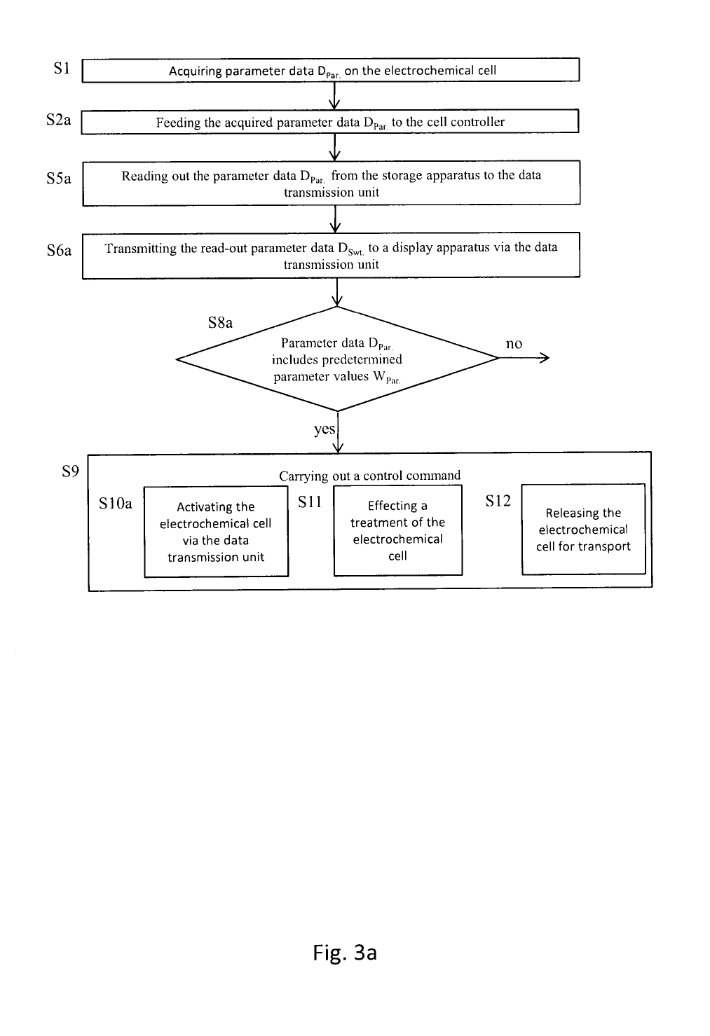

FIG. 5 a schematic depiction of the electrochemical cell according to a first cell embodiment,

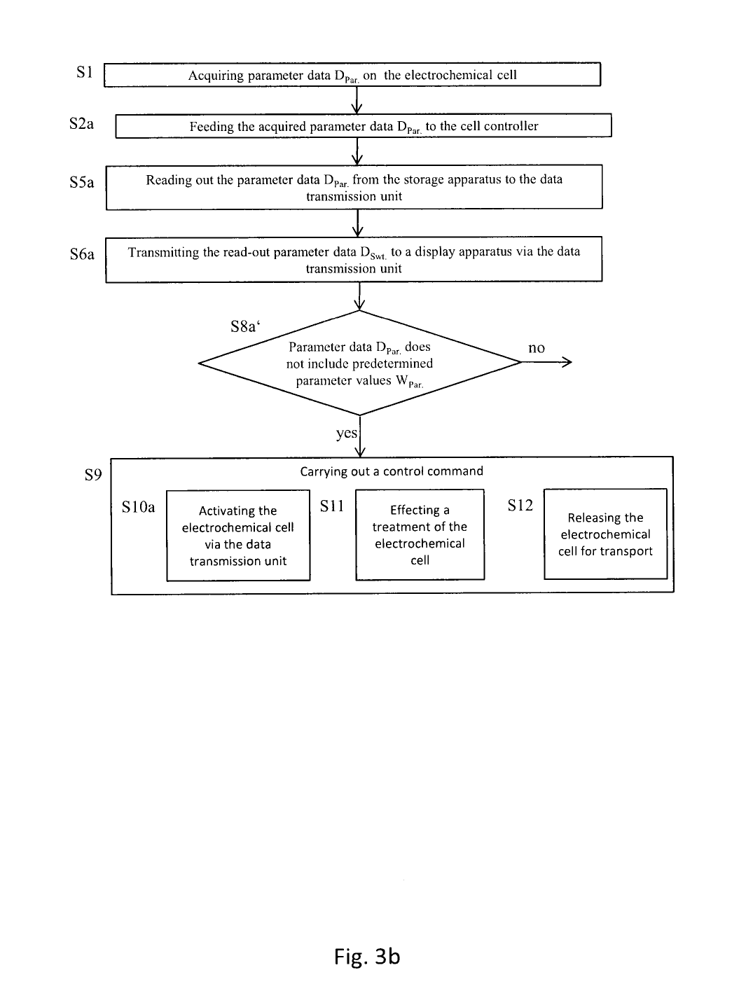

FIG. 6 a schematic depiction of the electrochemical cell according to a second cell embodiment,

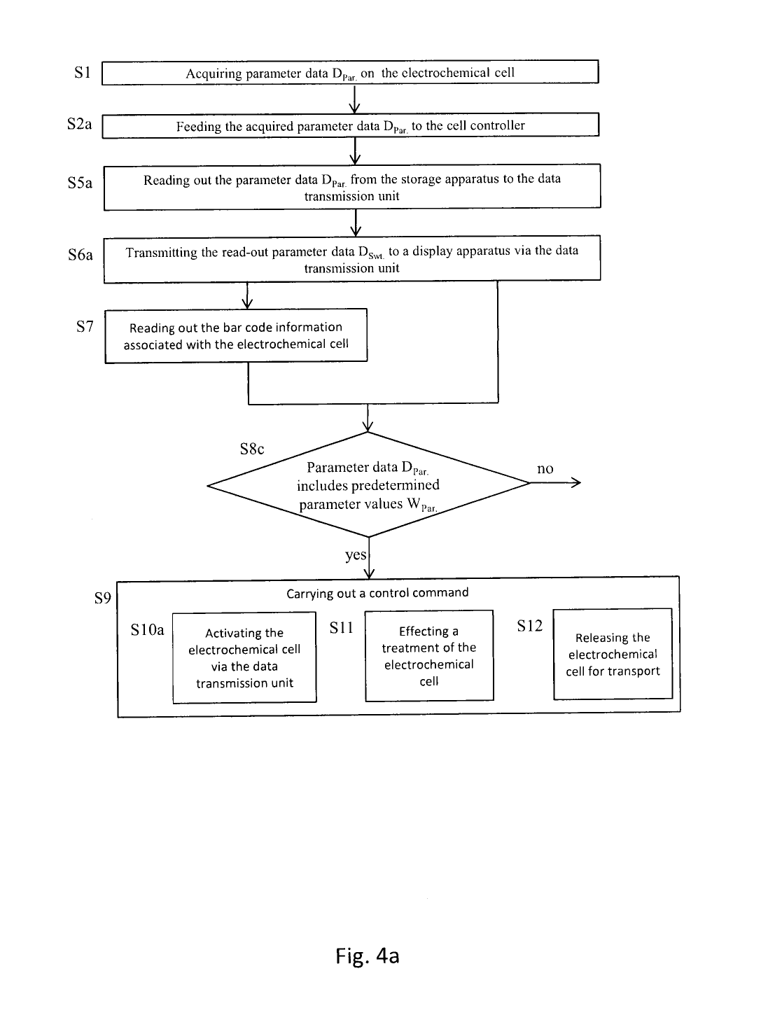

FIG. 7 a schematic depiction of the electrochemical cell according to a third cell embodiment, and

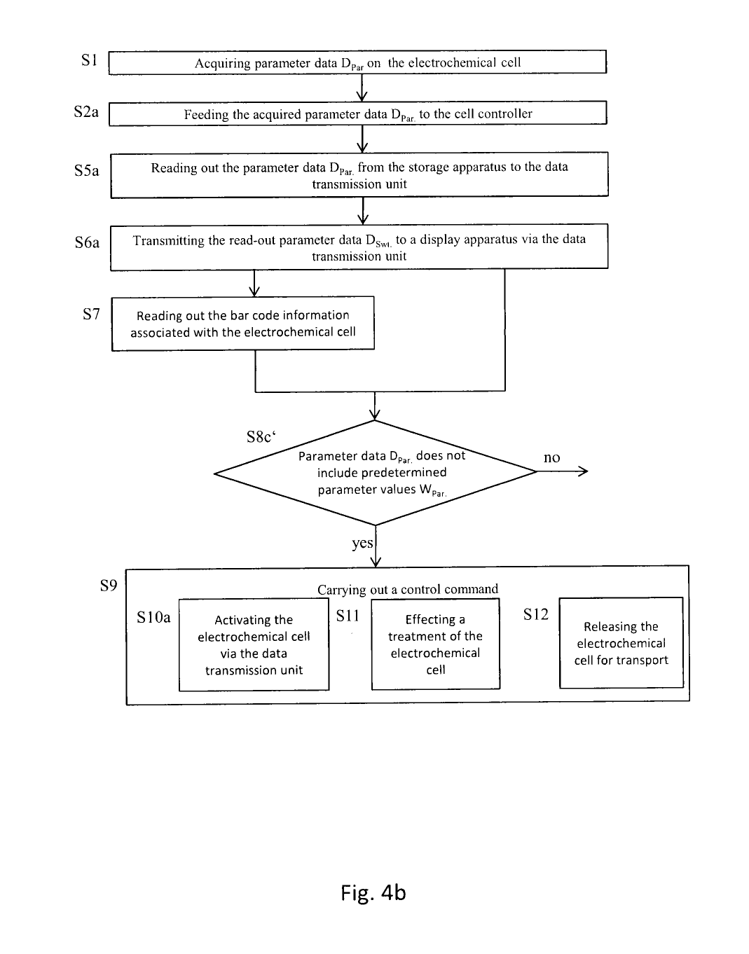

FIG. 8 a schematic depiction of the electrochemical cell according to a fourth cell embodiment.

FIG. 1a shows a flow chart of a first embodiment of a method for handling and servicing electrochemical cells 1 or a battery respectively according to the present invention. According to this embodiment, parameter data D_{Par.} on the electrochemical cell 1 or battery is acquired in step S1 and the acquired parameter data D_{Par.} is fed to a controller 3 in step S2. Preferably the controller 3 can be designed as a cell controller having battery management functions. The cell controller can furthermore also have battery management functions.

The controller 3 calculates control data D_{Swt} from the supplied parameter data D_{Par.} which is fed in a step S4 to a storage apparatus 5 which can preferably comprise a non-volatile memory, particularly a flash memory. The control data D_{Swt.} is fed to a data transmission unit 2 in a step S5 and the control data D_{Swt.} is transmitted to a display unit not depicted in the figures in a step S6. The data transmission unit 2 can have a connection for wired data transmission to the display unit or a component for wireless data transmission, particularly an RFID.

Whether the transmitted control data D_{Swt.} includes at least one predetermined control value W_{Swt.} is determined automatically and/or by a user of the display unit in a step S8. If the control data D_{Swt.} includes at least one predetermined control value, a command is prompted in step S9. Step S9 preferably includes at least one of the following steps: a step S10 of the data transmission unit 2 activating the electrochemical cell 1 or battery, a step S11 of effecting treatment of the electrochemical cell 1 or a step S12 of releasing the electrochemical cell 1 for transport.

FIG. 1b shows a flow chart of a modification of the first method embodiment for handling and servicing electrochemical cells 1 or a battery respectively. To avoid repetition, only the differences from the first embodiment will be described in the following and reference made to the latter's description for the other steps of the method. In this variation of the first embodiment, a step S8′ takes the place of step S8 and determines if the transmitted control data D_{Swt.} does not include a predetermined control value W_{Swt}. If the control data D_{Swt.} does not include a predetermined control value W_{Swt}, a command is prompted in step S9. According to the present invention, it is also possible in a further modification of the first embodiment not shown in the figures to determine in a step S8″ whether first predetermined control values W_{Swt.} are present and/or second predetermined control values W_{Swt.} are not present.

FIG. 2a shows a flow chart of a second embodiment of a method for handling and servicing electrochemical cells 1 or a battery respectively according to the present invention. To avoid repetition, only the differences from the first embodiment will be described in the following and reference made to the latter's description for the other steps of the method. In the second embodiment, the bar code information associated with the electrochemical cell 1 or battery is preferably read out with a bar code reader apparatus disposed on the display unit or assigned to same in a step S7, whereby whether the transmitted control data D_{Swt.} includes at least one predetermined control value W_{Swt.} is determined automatically and/or by a user of the display unit in step S8b as a function of the bar code information read out in step S7.

FIG. 2b shows a flow chart on a modification of the second method embodiment for handling and servicing electrochemical cells 1 or a battery respectively. To avoid repetition, only the differences from the second embodiment will be described in the following and reference made to the latter's description for the other steps of the method. In this variation of the second embodiment, a step S8b′ takes the place of step S8b and determines, based on the bar code information read out in step S7, if the transmitted control data D_{Swt.} does not include a predetermined control value W_{Swt}. If the control data D_{Swt.} does not include a predetermined control value W_{Swt}, a command is prompted in step S9. According to the present invention, it is also possible in a further modification of the first embodiment not shown in the figures to determine in a step S8″ as a function of the bar code information read out in step S7 whether first predetermined control values W_{Swt.} are present and/or second predetermined control values W_{Swt.} are not present.

FIG. 3a shows a flow chart of a third embodiment of a method for handling and servicing electrochemical cells 1 or a battery respectively according to the present invention. According to this embodiment, parameter data D_{Par.} on the electrochemical cell 1 or battery is acquired in step S1 and the acquired parameter data D_{Par.} is fed to a storage apparatus 5 which can preferably comprise a non-volatile memory, particularly a flash memory, in step S4a. The parameter data D_{Par.} is fed to a data transmission unit 2 in a step S5a and, in a step S6a, the parameter data D_{Par.} is transmitted to a display unit not depicted in the figures. The data transmission unit 2 can have a connection for wired data transmission to the display unit or a component for wireless data transmission, particularly an RFID.

Whether the transmitted parameter data D_{Par.} includes at least one predetermined parameter value W_{Par.} is determined automatically and/or by a user of the display unit in a step S8a. If the transmitted parameter data D_{Par.} includes at least one predetermined parameter value W_{Par.}, a command is prompted in step S9. Step S9 preferably includes at least one of the following steps: a step S10 of the data transmission unit 2 activating the electrochemical cell 1 or battery, a step S11 of effecting treatment of the electrochemical cell 1 or battery, or a step S12 of releasing the electrochemical cell 1 or battery for transport.

FIG. 3b shows a flow chart on a modification of the third method embodiment for handling and servicing electrochemical cells 1 or a battery respectively. To avoid repetition, only the differences from the third embodiment will be described in the following and reference made to the latter's description for the other steps of the method. In this variation of the third embodiment, a step S8′ takes the place of step S8 and determines if the transmitted para-meter data D_{Par.} does not include a predetermined parameter value W_{Par.}. If the transmitted parameter data D_{Par.} does not include a predetermined parameter value W_{Par.}, a command is prompted in step S9. According to the present invention, it is also possible in a further modification of the first embodiment not shown in the figures to determine in a step S8″ whether first predetermined parameter values W_{Par.} are present and/or second predetermined parameter values W_{Par.} are not present.

FIG. 4a shows a flow chart of a fourth embodiment of a method for handling and servicing electrochemical cells 1 or a battery respectively according to the present invention. To avoid repetition, only the differences from the third embodiment will be described in the following and reference made to the latter's description for the other steps of the method. In the second embodiment, the bar code information associated with the electrochemical cell 1 or battery is preferably read out with a bar code reader apparatus disposed on the display unit or assigned to same in a step S7, whereby whether the transmitted parameter data D_{Par.} includes at least one predetermined parameter value W_{Par.} is determined automatically and/or by a user of the display unit in step S8c as a function of the bar code information read out in step S7.

FIG. 4b shows a flow chart on a modification of the fourth method embodiment for handling and servicing electrochemical cells 1 or a battery respectively. To avoid repetition, only the differences from the fourth embodiment will be described in the following and reference made to the latter's description for the other steps of the method. In this variation of the fourth embodiment, a step S8c′ takes the place of step S8c and determines, based on the bar code information read out in step S7, if the transmitted parameter data D_{Par.} does not include a predetermined parameter value W_{Par}. If the parameter data D_{Par.} does not include a predetermined parameter value W_{Par.}, a command is prompted in step S9. According to the present invention, it is also possible in a further modification of the first embodiment not shown in the figures to determine in a step S8c″ as a function of the bar code information read out in step S7 whether first predetermined parameter values W_{Par.} are present and/or second predetermined parameter values W_{Par.} are not present.

FIGS. 5 to 8 show schematic plan view and cross-section depictions of embodiments of an electrochemical cell 1 according to the present invention.

In accordance with a first embodiment of a cell shown in FIG. 5, an electrochemical cell 1 comprises a data transmission unit 2, a controller 3, which can preferably be designed as a cell controller comprising battery management, a sensor 4 and a storage apparatus 5 which is preferably disposed on or in the cell controller 3 and can comprise a non-volatile memory, particularly a flash memory. According to the first embodiment shown in this figure, the sensor 4 can be connected to both the controller 3 as well as to the data transmission unit 2. The electrochemical cell 1 can further comprise a protective apparatus 6, preferably connected to the controller 3, particularly a PTC resistor or a power cutoff apparatus. Bar code information, not shown in the figure, can moreover be added to the electrochemical cell 1.

In accordance with a second embodiment of a cell shown in FIG. 6, it is also possible, in contrast to the first embodiment, for the sensor 4 not to be directly connected to the data transmission unit 2 but rather only connected indirectly to the data transmission unit 2 via the controller 3.

In accordance with a third embodiment of a cell shown in FIG. 7, it is also possible, in contrast to the first embodiment, for the sensor 4 to be connected to the protective apparatus 6.

In accordance with a fourth embodiment of a cell shown in FIG. 8, it is also possible, in contrast to the first embodiment, for the sensor 4 to not be directly connected to the data transmission unit 2 but rather only connected indirectly to the data transmission unit 2 via the controller 3 and for the sensor 4 to be connected to the protective apparatus 6.

According to further embodiments not shown in the figures, it is also possible for the storage apparatus 5 to not be allocated to the controller 3 but rather to the sensor 4 or the protective apparatus 6 or the data transmission unit 2.

The present invention further relates to a battery comprising said electrochemical cells, particularly a battery comprising said electrochemical cells designed for use in a motor vehicle.

### LIST OF REFERENCE NUMERALS

1 electrochemical cell
2 wireless signal transmission unit
3 cell controller
4 sensor
5 storage apparatus
6 protective apparatus
D_{Par} parameter data
D_{Swt} control data
W_{Par.}parameter value
W_{Swt.} control value
S1 acquiring parameter data on the electrochemical cell or battery
S2 feeding the acquired parameter data to the cell controller
S3 calculating control data as a function of the supplied parameter data
S4 feeding the control data to the storage apparatus
S4a feeding the acquired parameter data to the storage apparatus
S5 reading out the control data from the storage apparatus to the data transmission unit
S5a reading out the stored parameter data from the storage apparatus to the data transmission unit
S6 transmitting the read-out control data to the display apparatus via the data transmission unit
S6a transmitting the read-out parameter data to the display apparatus via the data transmission unit
S7 reading out the bar code information associated with the electrochemical cell or battery
S8 determining whether control data includes predetermined control values
S8′ determining whether control data does not include predetermined control values
S8a determining whether parameter data includes predetermined parameter values
S8a′ determining whether parameter data does not include predetermined parameter values
S8b determining whether control data includes predetermined control values as a function of the read-out bar code information
S8b′ determining whether control data does not include predetermined control values as a function of the read-out bar code information
S8c determining whether parameter data includes predetermined parameter values as a function of the read-out bar code information
S8c′ determining whether parameter data does not include predetermined parameter values as a function of the read-out bar code information
S9 effecting a command
S10 activating the electrochemical cell or battery via the data transmission unit
S11 effecting a treatment of the electrochemical cell or the battery
S12 releasing the electrochemical cell or battery for transport

1. A method for the handling and servicing of an electrochemical cell included in a battery having a plurality of electrochemical cells, at least one sensor connected to the controller to acquire parameter data on the electro-chemical cell, a storage apparatus including non-volatile memory, and a data transmission unit (2), the method comprising:
acquiring the parameter data on the electrochemical cell or battery respectively;
feeding the acquired parameter data to the controller;
calculating control data from the supplied parameter data in the controller;
feeding the control data to the storage apparatus;
reading out the control data from the storage apparatus to the data transmission unit;
wirelessly transmitting the read-out control data to a display apparatus via the data transmission unit; and
reading out associated bar code information from the electrochemical cell or battery respectively.

2. a method for the handling and servicing of an electrochemical cell including in a battery having a plurality of electrochemical cells at least one sensor to acquire parameter data on the electrochemical cell, a storage apparatus including non-volatile memory, and a data transmission unit, the method comprising:
acquiring parameter data on the electrochemical cell or battery respectively;
feeding the acquired parameter data to the storage apparatus;
reading out the stored parameter data from the storage apparatus to the data transmission unit;
wirelessly transmitting the read-out parameter data to a display apparatus via the data transmission unit; and
reading out associated bar code information from the electrochemical cell or battery respectively.

3. The method for the handling and servicing according to claim 1, wherein at least one parameter data on the electrochemical cell or battery to be acquired by the sensor is includes at least one of the following parameters:
the state of charge of the electrochemical cell or battery,
the temperature of the electrochemical cell or battery,
the voltage of the electrochemical cell or battery,
the load on the electrochemical cell or battery,
the charging characteristics of the electrochemical cell or battery,
the status of a protective apparatus, particularly a PTC resistor or a power cutoff apparatus,
the functioning of the sensor, or
the pressure in the electrochemical cell or battery.

4. (canceled)

5. The method for the handling and servicing according to claim 1, further comprising:
determining whether the control data includes predetermined control values, and determining whether the parameter data includes predetermined parameter values; and
effecting a command should the predetermined control values or predetermined parameter values be determined.

6. The method for the handling and servicing according to claim 1, further comprising:
determining whether the control data does not include predetermined control values or whether the parameter data does not include predetermined parameter values respectively; and
effecting a command should the predetermined control values or predetermined parameter values not be determined.

7. The method for the handling and servicing according to claim 4, further comprising:
determining whether the control data includes predetermined control values as a function of the bar code information read out or whether the parameter data includes predetermined parameter values as a function of the bar code information read out; and
effecting a command should the predetermined control values or predetermined parameter values be determined.

8. The method for the handling and servicing according to claim 4, further comprising:
determining whether the control data does not include predetermined control values as a function of the bar code information read out or whether the parameter data does not include predetermined parameter values as a function of the bar code information read out; and
effecting a command should the predetermined control values or predetermined parameter values are not determined.

9. The method for the handling and servicing according to claim 5, wherein the effecting of a command includes:
activating the electrochemical cell or battery via the data transmission unit,
effecting a treatment of the electrochemical cell or battery, or
releasing the electrochemical cell or battery for transport.

10. The method for the handling and servicing according to claim 1, wherein at least one parameter data on the electrochemical cell or battery to be acquired by the sensor:
a number of previous charging cycles in the electrochemical cell or battery,
characteristics of the previous charging cycles in the electrochemical cell or battery,
capacitance of the electrochemical cell or battery at a last full charge,
original capacitance of the electrochemical cell or battery,
maximum voltage of the electrochemical cell or battery at the last full charge,
original voltage of the electrochemical cell or battery, or
a manufacturer of the electrochemical cell or battery.

11. An electrochemical cell including a controller comprising at least one sensor to acquire parameter data on the electrochemical cell or a battery respectively, at least one storage apparatus including non-volatile memory a wireless data transmission unit, wherein the electrochemical cell is designed to perform a method according to claim 1.

12. The electrochemical cell according to claim 11, wherein the sensor is designed to acquire parameter data on the electrochemical cell or battery respectively which includes at least one of the following parameters:
a state of charge of the electrochemical cell or battery,
a temperature of the electrochemical cell or battery,
a voltage of the electrochemical cell or battery,
a load on the electrochemical cell or battery,
charging characteristics of the electrochemical cell or battery,
a status of a protective apparatus disposed on or in the electrochemical cell,
a functioning of the sensor, or
a pressure in the electrochemical cell or battery.

13. The electrochemical cell according to claim 11, wherein the sensor comprises at least one of the following sensor units:
a state of charge sensor unit,
a temperature sensor unit,
a voltage sensor unit, or
a pressure sensor unit.

14. The electrochemical cell according to claim 11, wherein the storage apparatus is designed to store at least one of the following parameters:
a number of previous charging cycles in the electrochemical cell or battery,
characteristics of a previous charging cycles in the electrochemical cell or battery,
a capacitance of the electrochemical cell or battery at a last full charge,
an original capacitance of the electrochemical cell or battery,
a maximum voltage of the electrochemical cell or battery at the last full charge,
an original voltage of the electrochemical cell or battery, or
a manufacturer of the electrochemical cell or battery.

15. The electrochemical cell according to claim 11, further comprising an activating apparatus designed to activate the electro-chemical cell or a battery respectively via the wireless signal transmission unit.

16. A battery comprising a plurality of electrochemical cells in accordance with claim 11.
